(19) United States
(12) Patent Application Publication
(10) Pub. No.: US 2024/0206307 A1
(43) Pub. Date: Jun. 20, 2024

(54) MANUFACTURING DEVICE OF DISPLAY DEVICE

(71) Applicant: Japan Display Inc., Tokyo (JP)

(72) Inventors: Takanobu TAKENAKA, Tokyo (JP); Masaru TAKAYAMA, Tokyo (JP); Yuki HAMADA, Tokyo (JP)

(73) Assignee: Japan Display Inc., Tokyo (JP)

(21) Appl. No.: 18/522,255

(22) Filed: Nov. 29, 2023

(30) Foreign Application Priority Data
Dec. 20, 2022 (JP) 2022-203272

(51) Int. Cl. H10K 71/16; C23C 14/02; C23C 14/12; C23C 14/24; C23C 14/50; C23C 14/56; H01L 21/677; H10K 71/60

(52) U.S. Cl. CPC H10K 71/164; C23C 14/028; C23C 14/12; C23C 14/24; C23C 14/505; C23C 14/566; H01L 21/67706; H01L 21/67718; H10K 71/60

(57) ABSTRACT

According to one embodiment, a manufacturing device of a display device includes first, second, third and fourth evaporation portions. A conveyance mechanism includes a first rail provided along the first evaporation portion, a second rail provided along the second evaporation portion, a third rail provided along the third evaporation portion, a fourth rail provided along the fourth evaporation portion, a first rotation chamber provided between the first rail and the second rail and between the third rail and the fourth rail and rotating the processing substrate which passed through the first rail and conveying the processing substrate to the fourth rail, and a gate valve provided between the first rotation chamber and the third and fourth rails.

### CROSS-REFERENCE TO RELATED APPLICATIONS

This application is based upon and claims the benefit of priority from Japanese Patent Application No. 2022-203272, filed Dec. 20, 2022, the entire contents of which are incorporated herein by reference.

### FIELD

Embodiments described herein relate generally to a manufacturing device of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In a device which manufactures such a display device, a technique which improves the efficiency of maintenance is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram showing a configuration example of a display element 20.

FIG. 12 is a diagram showing another configuration example of the display element 20.

FIG. 13 is a diagram showing a configuration example of a manufacturing device 100 of the display device DSP.

FIG. 14 is a cross-sectional view showing a configuration example of a typical evaporation chamber 121.

FIG. 15 is a diagram for explaining the first rotation chamber 110 shown in FIG. 13.

FIG. 16 is a diagram for explaining the second rotation chamber 120 shown in FIG. 13.

FIG. 17 is a diagram for explaining a first mode.

FIG. 18 is a diagram for explaining a second mode.

### DETAILED DESCRIPTION

Embodiments described herein aim to provide a manufacturing device of a display device in which the efficiency of maintenance can be improved.

In general, according to one embodiment, a manufacturing device of a display device comprises a preprocessing portion configured to perform preprocessing for a processing substrate comprising a lower electrode located above a substrate, a rib comprising an aperture which overlaps the lower electrode, and a partition including a lower portion located on the rib and an upper portion located on the lower portion and protruding from a side surface of the lower portion, a conveyance mechanism configured to convey the processing substrate which passed through the preprocessing portion, and first, second, third and fourth evaporation portions arranged in order in a conveyance direction of the processing substrate by the conveyance mechanism. Each of the first, second, third and fourth evaporation portions comprises a plurality of evaporation chambers. The conveyance mechanism comprises a first rail provided along the first evaporation portion, a second rail provided along the second evaporation portion, a third rail provided along the third evaporation portion, a fourth rail provided along the fourth evaporation portion, a first rotation chamber provided between the first rail and the second rail and between the third rail and the fourth rail, and configured to rotate the processing substrate which passed through the first rail and convey the processing substrate to the fourth rail, a second rotation chamber configured to rotate the processing substrate which passed through the second rail and convey the processing substrate to the third rail, and a gate valve provided between the first rotation chamber and the third and fourth rails.

According to another embodiment, a manufacturing device of a display device comprises a preprocessing portion configured to perform preprocessing for a processing substrate, a conveyance mechanism configured to convey the processing substrate which passed through the processing portion, and first, second, third and fourth evaporation portions arranged in order in a conveyance direction of the processing substrate by the conveyance mechanism. The first evaporation portion comprises an evaporation chamber for forming a first light emitting layer. The second evaporation portion comprises an evaporation chamber for forming an n-type charge generation layer and an evaporation chamber for forming a p-type charge generation layer. The third evaporation portion comprises an evaporation chamber for forming a second light emitting layer. The fourth evaporation portion comprises an evaporation chamber for forming an upper electrode. The conveyance mechanism comprises a first rail provided along the first evaporation portion, a second rail provided along the second evaporation portion, a third rail provided along the third evaporation portion, a fourth rail provided along the fourth evaporation portion, a first rotation chamber provided between the first rail and the second rail and between the third rail and the fourth rail and configured to rotate the processing substrate which passed through the first rail and convey the processing substrate to the fourth rail, a second rotation chamber configured to rotate the processing substrate which passed through the second rail and convey the processing substrate to the third rail, and a gate valve provided between the first rotation chamber and the third and fourth rails.

The embodiments can provide a manufacturing device of a display device in which the efficiency of maintenance can be improved.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. The X-axis, the Y-axis and the Z-axis are orthogonal to each other. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

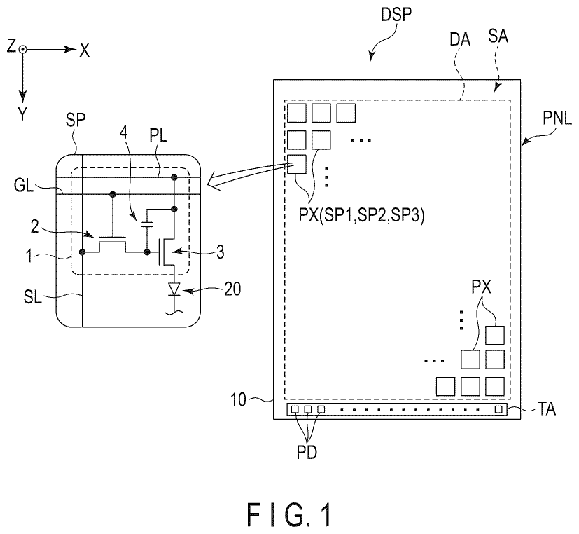

FIG. 1 is a diagram showing a configuration example of a display device DSP.

The display device DSP comprises a display panel PNL comprising a display area DA which displays an image and a surrounding area SA outside the display area DA on an insulating substrate 10. The substrate 10 may be glass or a resinous film having flexibility.

In the present embodiment, the substrate 10 is rectangular in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

The surrounding area SA comprises a terminal area TA for connecting an IC chip and a flexible printed circuit. The terminal area TA comprises a plurality of pads (terminals) PD. The pads PD are connected to the terminal of the IC chip and the terminal of the flexible printed circuit.

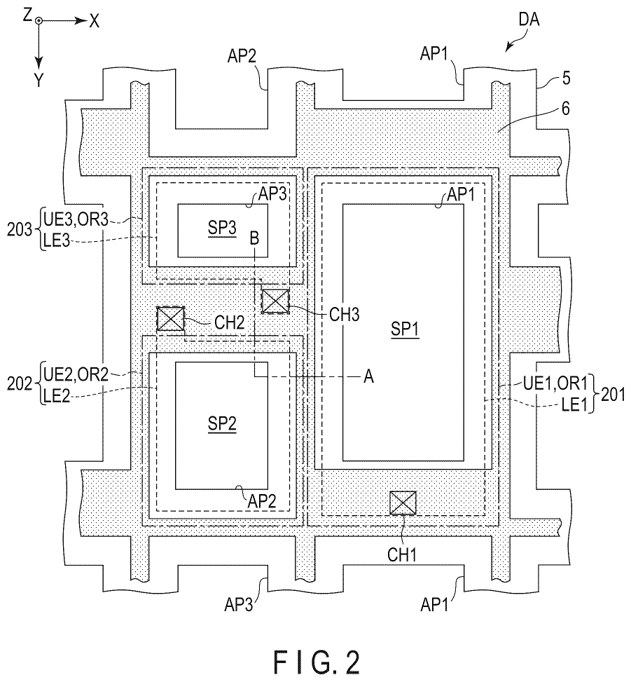

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 in plan view. The partition 6 is formed into a grating shape surrounding the apertures AP1, AP2 and AP3. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the rib 5. The organic layer OR1 and the upper electrode UE1 are surrounded by the partition 6. The peripheral portion of each of the organic layer OR1 and the upper electrode UE1 overlaps the rib 5 in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the rib 5. The organic layer OR2 and the upper electrode UE2 are surrounded by the partition 6. The peripheral portion of each of the organic layer OR2 and the upper electrode UE2 overlaps the rib 5 in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the rib 5. The organic layer OR3 and the upper electrode UE3 are surrounded by the partition 6. The peripheral portion of each of the organic layer OR3 and the upper electrode UE3 overlaps the rib 5 in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shapes of the lower electrodes, organic layers or upper electrodes shown in the figure do not necessarily reflect the accurate shapes.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

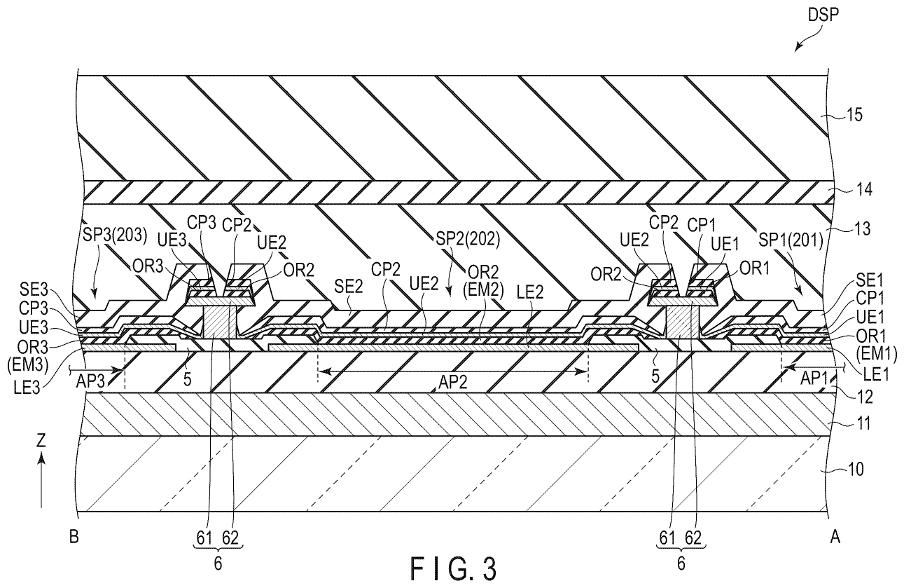

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The rib 5 is provided on the insulating layer 12 and the lower electrodes LE1, LE2 and LE3. The aperture AP1 of the rib 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the rib 5. Between, of the lower electrodes LE1, LE2 and LE3, the lower electrodes which are adjacent to each other, the insulating layer 12 is covered with the rib 5. The lower electrodes LE1, LE2 and LE3 are connected to the pixel circuits 1 of subpixels SP1, SP2 and SP3, respectively, through the contact holes provided in the insulating layer 12.

The partition 6 includes a conductive lower portion (stem) 61 provided on the rib 5 and an upper portion (hat) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. By this configuration, the both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the rib 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the rib 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the rib 5. The upper electrode UE3 covers the organic layer OR3 and is in contact with the lower portion 61.

In the example of FIG. 3, subpixel SP1 comprises a cap layer CP1 and a sealing layer SE1. Subpixel SP2 comprises a cap layer CP2 and a sealing layer SE2. Subpixel SP3 comprises a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers each member of subpixel SP1.

The sealing layer SE2 is provided on the cap layer CP2, is in contact with the partition 6 and continuously covers each member of subpixel SP2.

The sealing layer SE3 is provided on the cap layer CP3, is in contact with the partition 6 and continuously covers each member of subpixel SP3.

In the example of FIG. 3, the organic layer OR1, the upper electrode UE1 and the cap layer CP1 are partly located on the partition 6 around subpixel SP1. These portions are spaced apart from, of the organic layer OR1, the upper electrode UE1 and the cap layer CP1, the portions located in the aperture AP1 (the portions constituting the display element 201).

Similarly, the organic layer OR2, the upper electrode UE2 and the cap layer CP2 are partly located on the partition 6 around subpixel SP2. These portions are spaced apart from, of the organic layer OR2, the upper electrode UE2 and the cap layer CP2, the portions located in the aperture AP2 (the portions constituting the display element 202).

Similarly, the organic layer OR3, the upper electrode UE3 and the cap layer CP3 are partly located on the partition 6 around subpixel SP3. These portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. The resin layer 13 is covered with a sealing layer 14. The sealing layer 14 is covered with a resin layer 15.

Each of the rib 5, the sealing layers SE1, SE2 and SE3 and the sealing layer 14 is formed of, for example, an inorganic insulating material such as silicon nitride (SiNx). Each of the rib 5, the sealing layers SE1, SE2 and SE3 and the sealing layer 14 may be formed of another inorganic insulating material such as silicon oxide (SiOx), silicon oxynitride (SiON) or aluminum oxide (Al₂O₃).

The lower portion 61 of the partition 6 is formed of a conductive material and is electrically connected to the upper electrodes UE1, UE2 and UE3. Both the lower portion 61 and the upper portion 62 of the partition 6 may be formed of conductive materials.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

The circuit layer 11, insulating layer 12 and rib 5 shown in FIG. 3 are provided over the display area DA and the surrounding area SA.

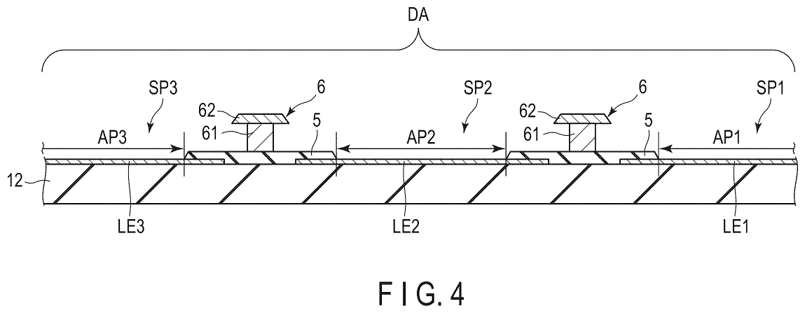

Now, this specification explains the manufacturing method of the display device DSP with reference to FIG. 4 to FIG. 10. In FIG. 4 to FIG. 10, the illustration of the lower side of the insulating layer 12 is omitted.

First, as shown in FIG. 4, after the lower electrodes LE1, LE2 and LE3 are formed on the insulating layer 12, the rib 5 comprising the apertures AP1, AP2 and AP3 and the partition 6 comprising the lower portion 61 and the upper portion 62 are formed. The aperture AP1 overlaps the lower electrode LE1 of subpixel SP1. The aperture AP2 overlaps the lower electrode LE2 of subpixel SP2. The aperture AP3 overlaps the lower electrode LE3 of subpixel SP3.

It should be noted that the partition 6 comprising the lower portion 61 and the upper portion 62 may be formed after the formation of the rib 5 comprising the apertures AP1, AP2 and AP3. Alternatively, the apertures AP1, AP2 and AP3 may be formed after the formation of the partition 6.

Subsequently, the display element 201 is formed.

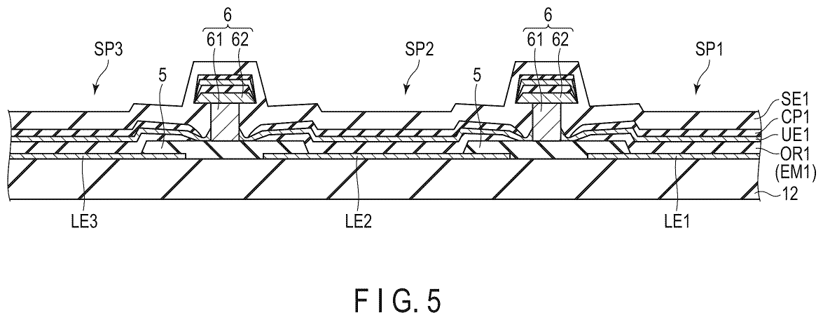

First, as shown in FIG. 5, the organic layer OR1 is formed by depositing the materials for forming the hole injection layer, the hole transport layer, the electron blocking layer, the light emitting layer (EM1), the hole blocking layer, the electron transport layer, the electron injection layer, etc., on the lower electrode LE1 in series.

Subsequently, the upper electrode UE1 is formed by depositing a mixture of magnesium and silver on the organic layer OR1. The upper electrode UE1 covers the organic layer OR1 and is in contact with the lower portion 61.

Subsequently, the cap layer CP1 is formed by depositing a high-refractive material and a low-refractive material on the upper electrode UE1.

As described later, the organic layer OR1, the upper electrode UE1 and the cap layer CP1 are successively formed by an in-line evaporation device in a state where a vacuum environment is maintained.

Subsequently, the sealing layer SE1 is formed so as to continuously cover the cap layer CP1 and the partition 6. The sealing layer SE1 is formed by a chemical vapor deposition (CVD) device.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from an evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

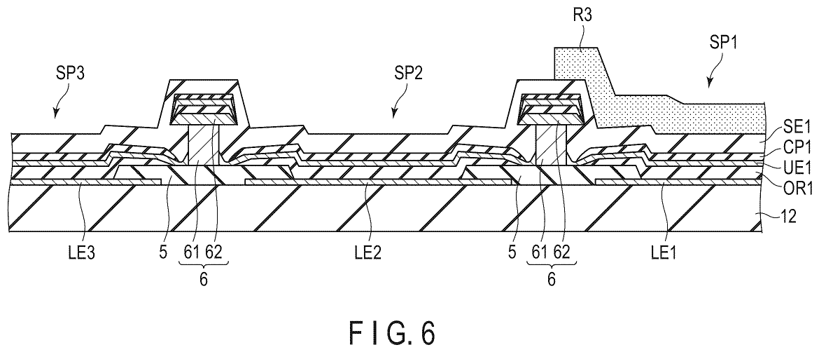

Subsequently, as shown in FIG. 6, a resist R3 having a predetermined shape is formed on the sealing layer SE1. The resist R3 overlaps subpixel SP1 and part of the partition 6 around subpixel SP1.

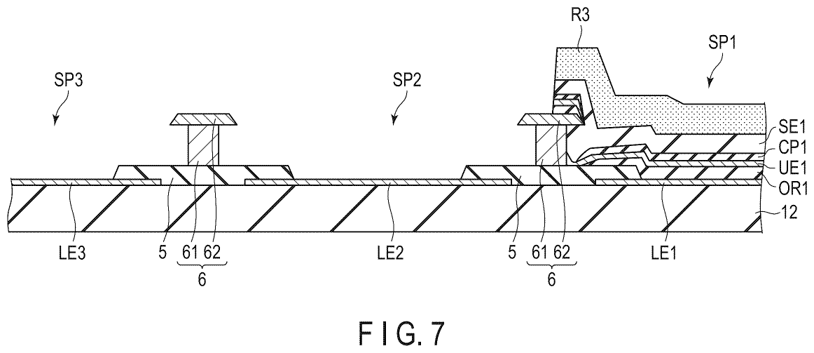

Subsequently, as shown in FIG. 7, the sealing layer SE1, cap layer CP1, upper electrode UE1 and organic layer OR1 exposed from the resist R3 are removed in series by etching using the resist R3 as a mask. In this manner, the lower electrode LE2 of subpixel SP2 and the lower electrode LE3 of subpixel SP3 are exposed.

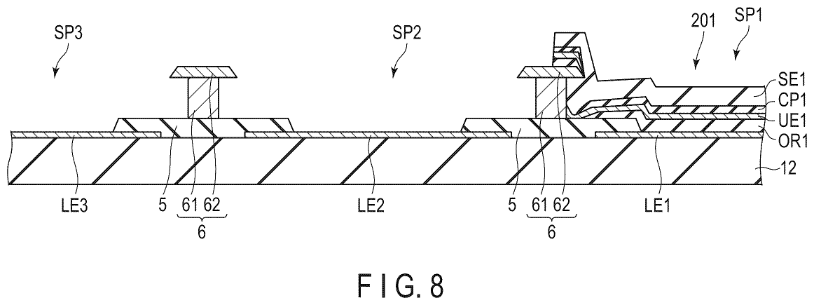

Subsequently, as shown in FIG. 8, the resist R3 is removed. By this process, the display element 201 is formed in subpixel SP1.

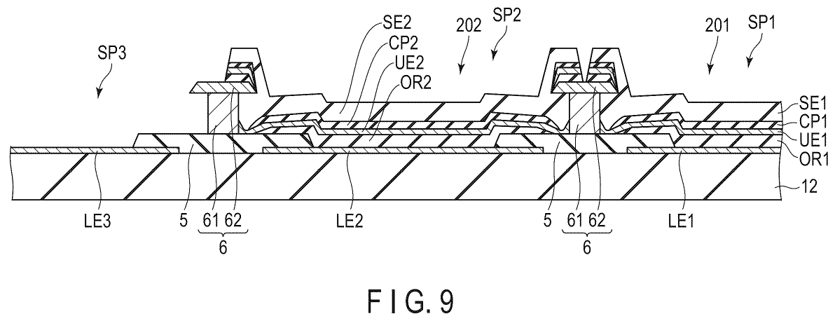

Subsequently, as shown in FIG. 9, the display element 202 is formed. The procedure of forming the display element 202 is similar to that of forming the display element 201. Specifically, the organic layer OR2 including the light emitting layer EM2, the upper electrode UE2, the cap layer CP2 and the sealing layer SE2 are formed in order on the lower electrode LE2. Subsequently, a resist is formed on the sealing layer SE2. The sealing layer SE2, the cap layer CP2, the upper electrode UE2 and the organic layer OR2 are patterned in series by etching using the resist as a mask. After this patterning, the resist is removed. In this manner, the display element 202 is formed in subpixel SP2, and the lower electrode LE3 of subpixel SP3 is exposed.

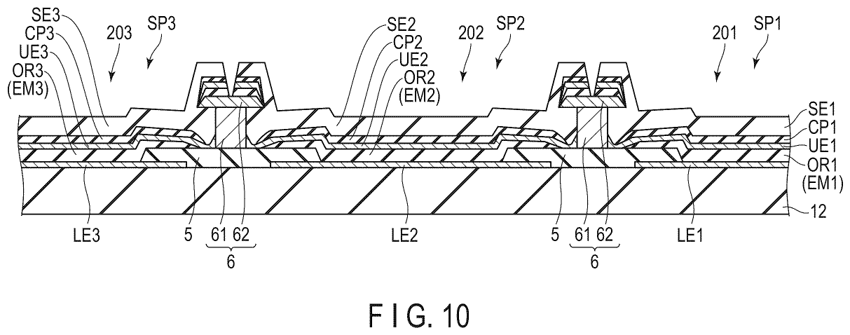

Subsequently, as shown in FIG. 10, the display element 203 is formed. The procedure of forming the display element 203 is similar to that of forming the display element 201. Specifically, the organic layer OR3 including the light emitting layer EM3, the upper electrode UE3, the cap layer CP3 and the sealing layer SE3 are formed in order on the lower electrode LE3. Subsequently, a resist is formed on the sealing layer SE3. The sealing layer SE3, the cap layer CP3, the upper electrode UE3 and the organic layer OR3 are patterned in series by etching using the resist as a mask. After this patterning, the resist is removed. By this process, the display element 203 is formed in subpixel SP3.

Subsequently, the resin layer 13, sealing layer 14 and resin layer 15 shown in FIG. 3 are formed in order. By this process, the display device DSP is completed.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Now, this specification explains a configuration example of the display element 20.

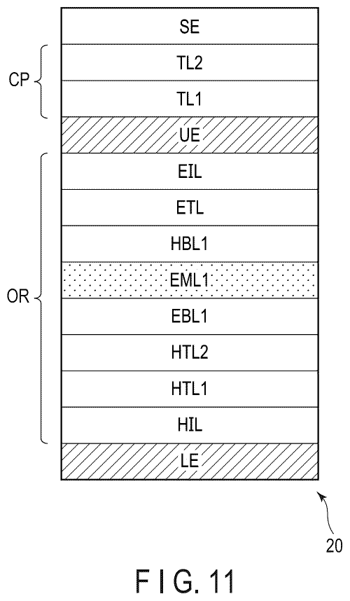

FIG. 11 is a diagram showing a configuration example of the display element 20.

The display element 20 shown in FIG. 11 could correspond to any one of the display elements 201, 202 and 203 described above.

Here, this specification explains an example in which the lower electrode LE corresponds to an anode and the upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL1, a hole transport layer HTL2, an electron blocking layer EBL1, a light emitting layer EML1, a hole blocking layer HBL1, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The hole transport layer HTL1 and the hole transport layer HTL2 may be formed of the same material or may be formed of materials which are different from each other.

The light emitting layer EML1 corresponds to one of the light emitting layers EM1, EM2 and EM3 shown in FIG. 3.

A cap layer CP includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2.

In this specification, the configuration of the organic layer OR shown in FIG. 11 is referred to as a single configuration.

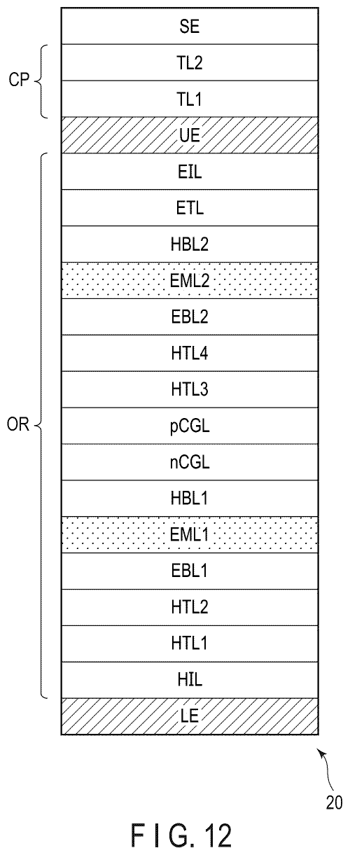

FIG. 12 is a diagram showing another configuration example of the display element 20.

The configuration example shown in FIG. 12 is different from the configuration example shown in FIG. 11 in terms of the layer structure of an organic layer OR.

The display element 20 shown in FIG. 12 could correspond to any one of the display elements 201, 202 and 203 described above.

Here, this specification explains an example in which the lower electrode LE corresponds to an anode and the upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL1, a hole transport layer HTL2, an electron blocking layer EBL1, a light emitting layer EML1, a hole blocking layer HBL1, an n-type charge generation layer nCGL, a p-type charge generation layer pCGL, a hole transport layer HTL3, a hole transport layer HTL4, an electron blocking layer EBL2, a light emitting layer EML2, a hole blocking layer HBL2, an electron transport layer ETL and an electron injection layer EIL are stacked in this order.

The hole transport layer HTL1, the hole transport layer HTL2, the hole transport layer HTL3 and the hole transport layer HTL4 may be formed of the same material or may be formed of materials which are different from each other.

The electron blocking layer EBL1 and the electron blocking layer EBL2 are formed of, for example, the same material. However, they may be formed of materials which are different from each other.

The light emitting layer EML1 and the light emitting layer EML2 are configured to emit light which exhibits the same color. The light emitting layer EML1 and the light emitting layer EML2 are formed of, for example, the same material. However, they may be formed of materials which are different from each other. Each of the light emitting layer EML1 and the light emitting layer EML2 corresponds to one of the light emitting layers EM1, EM2 and EM3 shown in FIG. 3.

The hole blocking layer HBL1 and the hole blocking layer HBL2 are formed of, for example, the same material. However, they may be formed of materials which are different from each other.

The n-type charge generation layer nCGL is a functional layer which supplies electrons to the light emitting layer EML1.

The p-type charge generation layer pCGL is a functional layer which supplies positive holes to the light emitting layer EML2.

A cap layer CP including a first transparent layer TL1 and a second transparent layer TL2 are provided on the upper electrode UE. A sealing layer SE (SE1, SE2 or SE3) is provided on the second transparent layer TL2.

In this specification, the configuration of the organic layer OR shown in FIG. 12 is referred to as a tandem configuration.

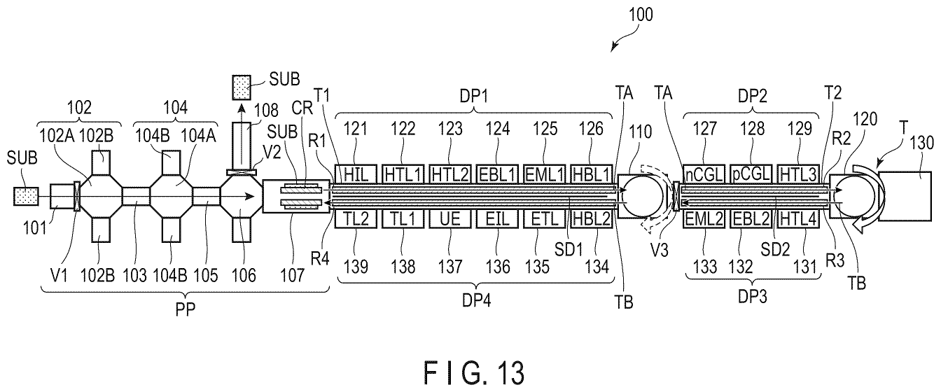

Now, this specification explains a manufacturing device 100 of the display device DSP with reference to FIG. 13.

The manufacturing device 100 explained here is an in-line evaporation device which can form either the display element 20 including the organic layer OR comprising the single configuration shown in FIG. 11 or the display element 20 including the organic layer OR comprising the tandem configuration shown in FIG. 12.

The manufacturing device 100 is applied in the process of successively forming the organic layer OR1, the upper electrode UE1 and the cap layer CP1 explained with reference to FIG. 5. As a matter of course, the manufacturing device 100 explained here can be also applied in the process of successively forming the organic layer OR2, the upper electrode UE2 and the cap layer CP2 or the process of successively forming the organic layer OR3, the upper electrode UE3 and the cap layer CP3.

No mask is provided in a processing substrate SUB which is supposed to be carried in the manufacturing device 100. In addition, no mask is placed in the processing substrate SUB inside the manufacturing device 100.

The processing substrate SUB which is supposed to be carried in the manufacturing device 100 comprises the lower electrodes LE1, LE2 and LE3, the rib 5 and the partition 6 as explained with reference to FIG. 4.

The manufacturing device 100 comprises a preprocessing portion PP, a first evaporation portion DP1, a second evaporation portion DP2, a third evaporation portion DP3, a fourth evaporation portion DP4 and a conveyance mechanism T.

The preprocessing portion PP is connected to the conveyance mechanism T.

The preprocessing portion PP is configured to perform predetermined preprocessing for the processing substrate SUB which was carried in. The preprocessing portion PP comprises a load lock chamber 101, a baking portion 102, a transfer chamber 103, a plasma processing portion 104, a transfer chamber 105, a handling chamber 106, an attaching/detaching portion 107 and a transfer chamber 108.

The load lock chamber 101 comprises a vacuum pump which decompresses the inside of the chamber after the processing substrate SUB comprising the lower electrodes, the rib, the partition, etc., is horizontally carried in the chamber.

The baking portion 102 comprises a handling chamber 102A, and a plurality of baking chambers 102B connected to the handling chamber 102A.

The handling chamber 102A is connected to the load lock chamber 101 via a gate valve V1 and is connected to the transfer chamber 103. The handling chamber 102A comprises a conveyance robot which extracts the processing substrate SUB which was carried in the load lock chamber 101, conveys the processing substrate SUB to one of the baking chambers 102B, extracts the processing substrate SUB which was conveyed to the baking chamber 102B and conveys the processing substrate SUB to the transfer chamber 103. Each baking chamber 102B comprises a heating mechanism for heating up the washed processing substrate SUB at a low temperature to remove moisture from the processing substrate SUB.

The plasma processing portion 104 comprises a handling chamber 104A connected to the transfer chamber 103 and the transfer chamber 105, and a plurality of plasma chambers 104B connected to the handling chamber 104A.

The handling chamber 104A comprises a conveyance robot which extracts the processing substrate SUB which was conveyed to the transfer chamber 103, conveys the processing substrate SUB to one of the plasma chambers 104B, extracts the processing substrate SUB which was conveyed to the plasma chamber 104B and conveys the processing substrate SUB to the transfer chamber 105. Each plasma chamber 104B comprises a plasma source which irradiates the processing substrate SUB with plasma to reform the surface of the lower electrode LE (LE1, LE2 or LE3).

The handling chamber 106 is connected to the transfer chamber 105 and the attaching/detaching portion 107. The handling chamber 106 is connected to the transfer chamber 108 via a gate valve V2. The handling chamber 106 comprises a conveyance robot which extracts the processing substrate SUB which was conveyed to the transfer chamber 105, conveys the processing substrate SUB to the attaching/detaching portion 107, extracts the processing substrate SUB which was conveyed to the attaching/detaching portion 107 and conveys the processing substrate SUB to the transfer chamber 108.

The transfer chamber 108 is connected to a CVD device for forming the sealing layer SE.

The attaching/detaching portion 107 comprises a mechanism for securing the processing substrate SUB which was conveyed by the handling chamber 106 to a dedicated carrier CR by an electrostatic chuck and detaching the processing substrate SUB from the carrier CR by releasing the securing applied by the electrostatic chuck.

In the example shown in the figure, the attaching/detaching portion 107 comprises a mechanism for rotating the processing substrate SUB which was conveyed horizontally by 90 degrees to raise the processing substrate SUB perpendicularly and rotating the processing substrate SUB which was conveyed perpendicularly by 90 degrees to lay down the processing substrate SUB horizontally.

The attaching/detaching portion 107 conveys the carrier CR to which the processing substrate SUB is secured to the conveyance mechanism T and receives the carrier CR which was conveyed from the conveyance mechanism T. The conveyance mechanism T is configured to convey the processing substrate SUB having a perpendicular posture.

The conveyance mechanism T comprises a first conveyance portion T1, a second conveyance portion T2, a first rotation chamber 110, a second rotation chamber 120 and a gate valve V3.

The first conveyance portion T1 is connected to the attaching/detaching portion 107 and the first rotation chamber 110. The first conveyance portion T1 comprises a first rail R1 and a fourth rail R4. A shielding plate SD1 for preventing the scattering of evaporation materials is provided between the first rail R1 and the fourth rail R4.

The second conveyance portion T2 is connected to the first rotation chamber 110 via the gate valve V3. The second conveyance portion T2 is connected to the second rotation chamber 120. The second conveyance portion T2 comprises a second rail R2 and a third rail R3. A shielding plate SD2 for preventing the scattering of evaporation materials is provided between the second rail R2 and the third rail R3.

The first rail R1 and the second rail R2 are provided to convey the processing substrate SUB and the carrier CR in the conveyance direction TA shown by an arrow in the figure. The first rail R1 and the second rail R2 extend on the same straight line.

The third rail R3 and the fourth rail R4 are provided to convey the processing substrate SUB and the carrier CR in the conveyance direction TB shown by an arrow in the figure. The conveyance direction TB is the opposite direction of the conveyance direction TA. The third rail R3 and the fourth rail R4 extend on the same straight line. The first rail R1 and the fourth rail R4 are parallel to each other. The second rail R2 and the third rail R3 are parallel to each other.

The first rotation chamber 110 and the second rotation chamber 120 are configured to rotate the processing substrate SUB and the carrier CR and convert the conveyance direction 180°.

The conveyance mechanism T comprises a storage portion 130 connected to the second rotation chamber 120. For example, the storage portion 130 is provided to temporarily store the carrier CR at the time of the maintenance of the manufacturing device 100.

The first evaporation portion DP1 and the second evaporation portion DP2 are arranged in order in the conveyance direction TA of the processing substrate SUB and the carrier CR by the conveyance mechanism T.

The third evaporation portion DP3 and the fourth evaporation portion DP4 are arranged in order in the conveyance direction TB of the processing substrate SUB and the carrier CR by the conveyance mechanism T.

The first evaporation portion DP1 and the fourth evaporation portion DP4 face each other across the intervening first conveyance portion T1 of the conveyance mechanism T.

The second evaporation portion DP2 and the third evaporation portion DP3 face each other across the intervening second conveyance portion T2 of the conveyance mechanism T.

Each of the first evaporation portion DP1, the second evaporation portion DP2, the third evaporation portion DP3 and the fourth evaporation portion DP4 comprises at least one evaporation chamber. In the example shown in the figure, each of the first evaporation portion DP1, the second evaporation portion DP2, the third evaporation portion DP3 and the fourth evaporation portion DP4 comprises a plurality of evaporation chambers.

The first evaporation portion DP1 comprises evaporation chambers 121 to 126.

The evaporation chambers 121 to 126 are arranged in order in the conveyance direction TA of the first conveyance portion T1. The first rail R1 is provided along the evaporation chambers 121 to 126 of the first evaporation portion DP1.

The evaporation chamber 121 is configured to form the hole injection layer HIL on the lower electrode LE.

The evaporation chamber 122 is configured to form the hole transport layer HTL1 on the hole injection layer HIL.

The evaporation chamber 123 is configured to form the hole transport layer HTL2 on the hole transport layer HTL1.

The evaporation chamber 124 is configured to form the electron blocking layer (first electron blocking layer) EBL1 on the hole transport layer HTL2.

The evaporation chamber 125 is configured to form the light emitting layer (first light emitting layer) EML1 on the electron blocking layer EBL1.

The evaporation chamber 126 is configured to form the hole blocking layer (first hole blocking layer) HBL1 on the light emitting layer EML1.

The second evaporation portion DP2 comprises evaporation chambers 127 to 129.

The evaporation chambers 127 to 129 are arranged in order in the conveyance direction TA of the second conveyance portion T2. The second rail R2 is provided along the evaporation chambers 127 to 129 of the second evaporation portion DP2.

The evaporation chamber 127 is configured to form the n-type charge generation layer nCGL on the hole blocking layer HBL1.

The evaporation chamber 128 is configured to form the p-type charge generation layer pCGL on the n-type charge generation layer nCGL.

The evaporation chamber 129 is configured to form the hole transport layer HTL3 on the p-type charge generation layer pCGL.

The third evaporation portion DP3 comprises evaporation chambers 131 to 133.

The evaporation chambers 131 to 133 are arranged in order in the conveyance direction TB of the second conveyance portion T2. The third rail R3 is provided along the evaporation chambers 131 to 133 of the third evaporation portion DP3.

The evaporation chamber 131 is configured to form the hole transport layer HTL4 on the hole transport layer HTL3.

The evaporation chamber 132 is configured to form the electron blocking layer (second electron blocking layer) EBL2 on the hole transport layer HTL4.

The evaporation chamber 133 is configured to form the light emitting layer (second light emitting layer) EML2 on the electron blocking layer EBL2. The light emitting layer EML2 is configured to emit light which exhibits the same color as the light emitting layer EML1.

The fourth evaporation portion DP4 comprises evaporation chambers 134 to 139.

The evaporation chambers 134 to 139 are arranged in order in the conveyance direction TB of the first conveyance portion T1. The fourth rail R4 is provided along the evaporation chambers 134 to 139 of the fourth evaporation portion DP4.

The evaporation chamber 134 is configured to form the hole blocking layer (second hole blocking layer) HBL2 on the light emitting layer EML2.

The evaporation chamber 135 is configured to form the electron transport layer ETL on the hole blocking layer HBL2.

The evaporation portion 136 is configured to form the electron injection layer EIL on the electron transport layer ETL.

The evaporation chamber 137 is configured to form the upper electrode UE on the electron injection layer EIL.

The evaporation chamber 138 is configured to form the first transparent layer TL1 on the upper electrode UE.

The evaporation chamber 139 is configured to form the second transparent layer TL2 on the first transparent layer TL1.

It should be noted that the evaporation chambers provided in each of the first evaporation portion DP1, the second evaporation portion DP2, the third evaporation portion DP3 and the fourth evaporation portion DP4 are not limited to the example shown in FIG. 13.

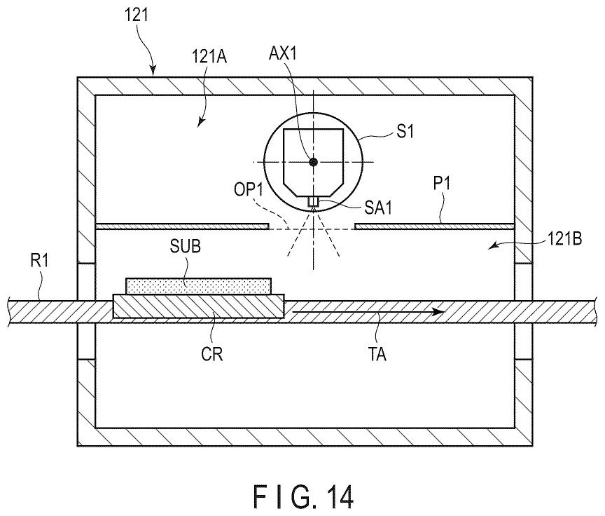

FIG. 14 is a cross-sectional view showing a configuration example of the typical evaporation chamber 121.

The evaporation chamber 121 comprises a partition plate P1. The partition plate P1 partitions the evaporation chamber 121 into a first space 121A and a second space 121B. An evaporation source S1 is accommodated in the first space 121A. The second space 121B is a space in which the processing substrate SUB is conveyed together with the carrier CR. In the second space 121B, the first rail R1 is provided. The evaporation source S1 is configured to emit a material for forming the hole injection layer HIL.

The other evaporation chambers 122 to 139 shown in FIG. 13 are configured in the same manner as the evaporation chamber 121 shown in FIG. 14.

The evaporation source accommodated in each evaporation chamber is configured to heat a material, evaporate the material and continuously emit the material while the manufacturing device 100 operates. In a mode in which the emitted material is deposited on the processing substrate SUB, the evaporation source is set such that the discharge port faces the second space. In a mode in which the emitted material is not deposited on the processing substrate SUB, the evaporation source is set such that the discharge port faces the first space.

For example, in the evaporation chamber 121, the evaporation source S1 is configured to rotate around a rotation axis AX1. The evaporation source S1 extends along the rotation axis AX1. The partition plate P1 comprises an opening OP1 shown by the dotted line. The opening OP1 faces the evaporation source S1.

In the example shown in the figure, the evaporation source S1 is set so as to be in a mode in which the emitted material is deposited on the processing substrate SUB, and a discharge port SA1 faces the second space 121B. By this configuration, the material emitted from the evaporation source S1 is deposited on the processing substrate SUB which is conveyed together with the carrier CR.

To the contrary, in a mode (non-operation state) in which the emitted material is not deposited on the processing substrate SUB, the evaporation source S1 rotates around the rotation axis AX1 such that the discharge port SA1 faces the first space 121A. By this configuration, the material emitted from the evaporation source S1 is not deposited on the processing substrate SUB which is conveyed with the carrier CR. It should be noted that a shutter which can block the opening OP1 may be provided.

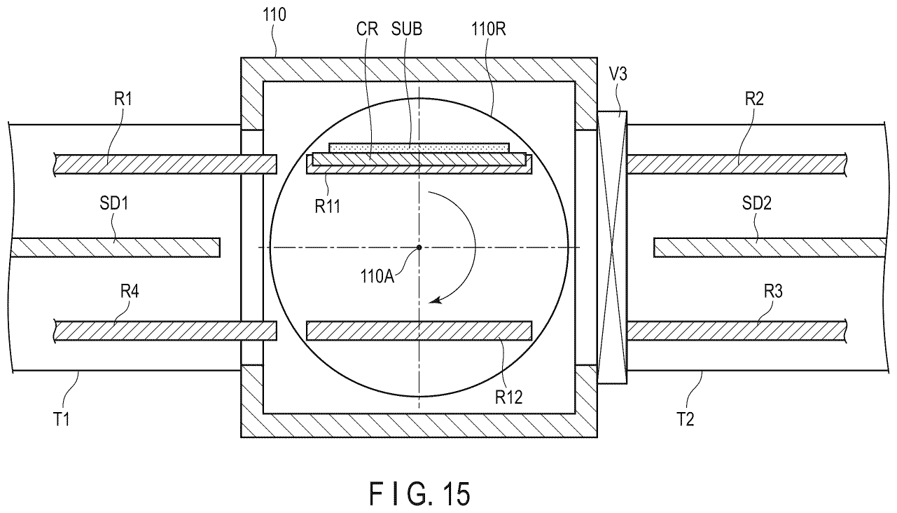

FIG. 15 is a diagram for explaining the first rotation chamber 110 shown in FIG. 13.

The first rotation chamber 110 comprises a rotation mechanism 110R. The rotation mechanism 110R is configured to rotate around a rotation axis 110A. The rotation axis 110A is parallel to the normal relative to the horizontal plane.

The rotation mechanism 110R comprises a rail R11 and a rail R12.

The rail R11 is provided between the first rail R1 and the second rail R2, is located on the same straight line as the first rail R1 and the second rail R2, and is spaced apart from the first rail R1 and the second rail R2.

The rail R12 is provided between the third rail R3 and the fourth rail R4, is located on the same straight line as the third rail R3 and the fourth rail R4, and is spaced apart from the third rail R3 and the fourth rail R4.

The gate valve V3 is provided between the rail R11 and the second rail R2 and between the rail R12 and the third rail R3.

In a first mode for forming the organic layer OR comprising the single configuration shown in FIG. 11, after the processing substrate SUB and carrier CR having a perpendicular posture are conveyed to the rail R11 via the first rail R1, the rotation mechanism 110R rotates 180° around the rotation axis 110A in the horizontal plane while holding the processing substrate SUB and the carrier CR. Subsequently, the processing substrate SUB and the carrier CR are conveyed to the fourth rail R4.

In a second mode for forming the organic layer OR comprising the tandem configuration shown in FIG. 12, the rotation mechanism 110R does not rotate. Thus, the processing substrate SUB and the carrier CR are conveyed to the second rail R2 after being conveyed to the rail R11 via the first rail R1. The processing substrate SUB and the carrier CR are conveyed to the fourth rail R4 after being conveyed to the rail R12 via the third rail R3.

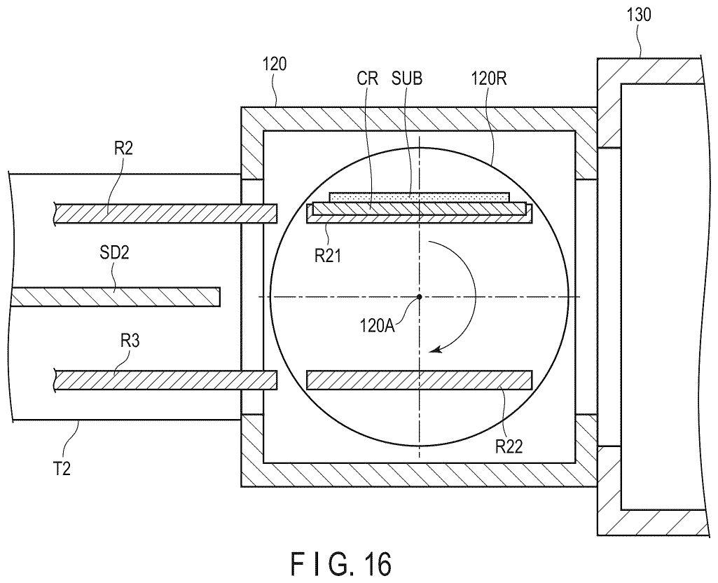

FIG. 16 is a diagram for explaining the second rotation chamber 120 shown in FIG. 13.

The second rotation chamber 120 comprises a rotation mechanism 120R. The rotation mechanism 120R is configured to rotate around a rotation axis 120A. The rotation axis 120A is parallel to the normal relative to the horizontal plane.

The rotation mechanism 120R comprises a rail R21 and a rail R22.

The rail R21 is located on the same straight line as the second rail R2 and is spaced apart from the second rail R2.

The rail R22 is located on the same straight line as the third rail R3 and is spaced apart from the third rail R3.

In the second mode, after the processing substrate SUB and carrier CR having a perpendicular posture are conveyed to the rail R21 via the second rail R2, the rotation mechanism 120R rotates 180° around the rotation axis 120A in the horizontal plane while holding the processing substrate SUB and the carrier CR. Subsequently, the processing substrate SUB and the carrier CR are conveyed to the third rail R3.

In the first mode, the second rotation chamber 120 is not used.

Now, this specification explains the first mode and second mode of the manufacturing device 100.

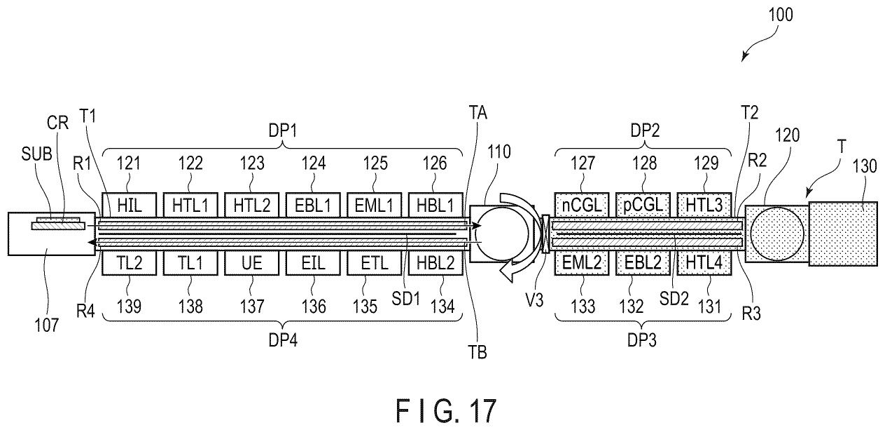

FIG. 17 is a diagram for explaining the first mode. In FIG. 17, the illustration of part of the preprocessing portion is omitted.

The first conveyance portion T1, the first rotation chamber 110, the evaporation chambers 121 to 126 of the first evaporation portion DP1 and the evaporation chambers 134 to 139 of the fourth evaporation portion DP4 are maintained as a vacuum. Here, the vacuum state corresponds to a decompression state lower than atmospheric pressure.

The gate valve V3 is closed. Thus, the second conveyance portion T2, the second rotation chamber 120, the storage portion 130, the evaporation chambers 127 to 129 of the second evaporation portion DP2 and the evaporation chambers 131 to 133 of the third evaporation portion DP3 can be opened to the atmosphere.

In the attaching/detaching portion 107, the processing substrate SUB and the carrier CR are conveyed along the first rail R1.

First, in the evaporation chamber 121, the material for forming the hole injection layer HIL is emitted to the processing substrate SUB, and thus, the hole injection layer HIL is formed on the lower electrode LE.

Subsequently, in the evaporation chamber 122, the material for forming the hole transport layer HTL1 is emitted to the processing substrate SUB, and thus, the hole transport layer HTL1 is formed on the hole injection layer HIL.

Subsequently, in the evaporation chamber 123, the material for forming the hole transport layer HTL2 is emitted to the processing substrate SUB, and thus, the hole transport layer HTL2 is formed on the hole transport layer HTL1.

Subsequently, in the evaporation chamber 124, the material for forming the electron blocking layer EBL1 is emitted to the processing substrate SUB, and thus, the electron blocking layer EBL1 is formed on the hole transport layer HTL2.

Subsequently, in the evaporation chamber 125, the material for forming the light emitting layer EML1 is emitted to the processing substrate SUB, and thus, the light emitting layer EML1 is formed on the electron blocking layer EBL1.

Subsequently, in the evaporation chamber 126, the material for forming the hole blocking layer HBL1 is emitted to the processing substrate SUB, and thus, the hole blocking layer HBL1 is formed on the light emitting layer EML1.

The processing substrate SUB and carrier CR which passed through the first rail R1 are conveyed to the first rotation chamber 110.

In the first rotation chamber 110, as shown in FIG. 15, after the processing substrate SUB and carrier CR which passed through the first rail R1 are conveyed to the rail R11 of the rotation mechanism 110R, the rotation mechanism 110R rotates 180°, and the processing substrate SUB and the carrier CR are conveyed to the fourth rail R4.

Subsequently, the processing substrate SUB and the carrier CR are conveyed along the fourth rail R4.

In the first mode, the evaporation chamber 134 is maintained in a non-operation state. Thus, the processing substrate SUB and the carrier CR pass through the evaporation chamber 134. It should be noted that the evaporation chamber 126 may be maintained in a non-operation state to form the hole blocking layer HBL2 on the light emitting layer EML1 in the evaporation chamber 134.

In the non-operation state described here, as explained with reference to FIG. 14, the discharge port of the evaporation source may be maintained so as to face the first space, or the opening of the partition plate may be blocked by a shutter. Alternatively, the non-operation state may be a state in which the evaporation source is not heated such that no material is emitted from the evaporation source.

Subsequently, in the evaporation chamber 135, the material for forming the electron transport layer ETL is emitted to the processing substrate SUB, and thus, the electron transport layer ETL is formed on the hole blocking layer HBL1.

Subsequently, in the evaporation chamber 136, the material for forming the electron injection layer EIL is emitted to the processing substrate SUB, and thus, the electron injection layer EIL is formed on the electron transport layer ETL.

Subsequently, in the evaporation chamber 137, the material for forming the upper electrode UE is emitted to the processing substrate SUB, and thus, the upper electrode UE is formed on the electron injection layer EIL.

Subsequently, in the evaporation chamber 138, the material for forming the first transparent layer TL1 is emitted to the processing substrate SUB, and thus, the first transparent layer TL1 is formed on the upper electrode UE.

Subsequently, in the evaporation chamber 139, the material for forming the second transparent layer TL2 is emitted to the processing substrate SUB, and thus, the second transparent layer TL2 is formed on the first transparent layer TL1.

The processing substrate SUB and carrier CR which passed through the fourth rail R4 are conveyed to the attaching/detaching portion 107. In the attaching/detaching portion 107, the processing substrate SUB is released from the carrier CR, is conveyed to the transfer chamber 108, and is conveyed to a CVD device (not shown).

By this process, the display element 20 comprising the organic layer OR comprising a single configuration is formed.

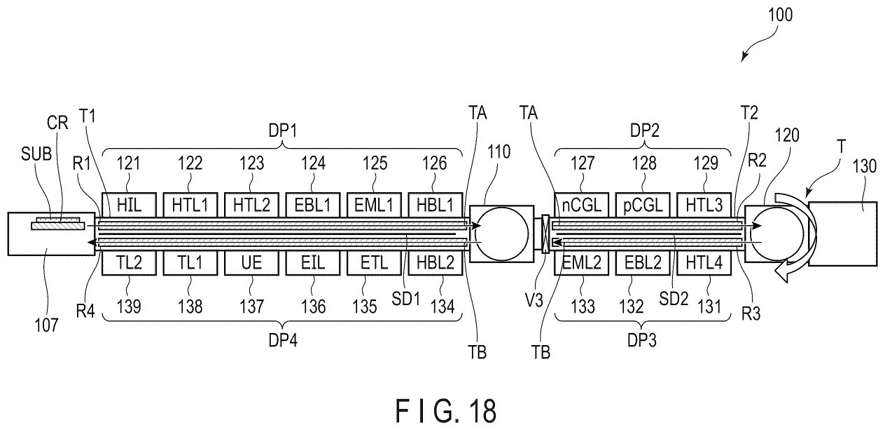

FIG. 18 is a diagram for explaining the second mode. In FIG. 18, the illustration of part of the preprocessing portion is omitted.

The first conveyance portion T1, the second conveyance portion T2, the first rotation chamber 110, the second rotation chamber 120, the storage portion 130, the evaporation chambers 121 to 126 of the first evaporation portion DP1, the evaporation chambers 127 to 129 of the second evaporation portion DP2, the evaporation chambers 131 to 133 of the third evaporation portion DP3 and the evaporation chambers 134 to 139 of the fourth evaporation portion DP4 are maintained as a vacuum.

The gate valve V3 is opened at a time when the processing substrate SUB and the carrier CR are conveyed between the first rotation chamber 110 and the second conveyance portion T2.

In the attaching/detaching portion 107, the processing substrate SUB and the carrier CR are conveyed along the first rail R1.

First, the hole injection layer HIL is formed on the lower electrode LE in the evaporation chamber 121.

Subsequently, the hole transport layer HTL1 is formed on the hole injection layer HIL in the evaporation chamber 122.

Subsequently, the hole transport layer HTL2 is formed on the hole transport layer HTL1 in the evaporation chamber 123.

Subsequently, the electron blocking layer EBL1 is formed on the hole transport layer HTL2 in the evaporation chamber 124.

Subsequently, the light emitting layer EML1 is formed on the electron blocking layer EBL1 in the evaporation chamber 125.

Subsequently, the hole blocking layer HBL1 is formed on the light emitting layer EML1 in the evaporation chamber 126.

The processing substrate SUB and carrier CR which passed through the first rail R1 are conveyed to the first rotation chamber 110.

In the first rotation chamber 110, as shown in FIG. 15, after the processing substrate SUB and carrier CR which passed through the first rail R1 are conveyed to the rail R11 of the rotation mechanism 110R, the processing substrate SUB and the carrier CR are conveyed to the second rail R2 via the gate valve V3.

Subsequently, the processing substrate SUB and the carrier CR are conveyed along the second rail R2.

The n-type charge generation layer nCGL is formed on the hole blocking layer HBL1 in the evaporation chamber 127.

Subsequently, the p-type charge generation layer pCGL is formed on the n-type charge generation layer nCGL in the evaporation chamber 128.

Subsequently, the hole transport layer HTL3 is formed on the p-type charge generation layer pCGL in the evaporation chamber 129.

The processing substrate SUB and carrier CR which passed through the second rail R2 are conveyed to the second rotation chamber 120.

In the second rotation chamber 120, as shown in FIG. 16, after the processing substrate SUB and carrier CR which passed through the second rail R2 are conveyed to the rail R21 of the rotation mechanism 120R, the rotation mechanism 120R rotates 180°, and the processing substrate SUB and the carrier CR are conveyed to the third rail R3.

Subsequently, the processing substrate SUB and the carrier CR are conveyed along the third rail R3.

The hole transport layer HTL4 is formed on the hole transport layer HTL3 in the evaporation chamber 131.

Subsequently, the electron blocking layer EBL2 is formed on the hole transport layer HTL4 in the evaporation chamber 132.

Subsequently, the light emitting layer EML2 is formed on the electron blocking layer EBL2 in the evaporation chamber 133.

The processing substrate SUB and carrier CR which passed through the third rail R3 are conveyed to the first rotation chamber 110.

In the first rotation chamber 110, as shown in FIG. 15, after the processing substrate SUB and carrier CR which passed through the third rail R3 are conveyed to the rail R12 of the rotation mechanism 110R, the processing substrate SUB and the carrier CR are conveyed to the fourth rail R4.

Subsequently, the processing substrate SUB and the carrier CR are conveyed along the fourth rail R4.

The hole blocking layer HBL2 is formed on the light emitting layer EML2 in the evaporation chamber 134.

Subsequently, the electron transport layer ETL is formed on the hole blocking layer HBL2 in the evaporation chamber 135.

Subsequently, the electron injection layer EIL is formed on the electron transport layer ETL in the evaporation chamber 136.

Subsequently, the upper electrode UE is formed on the electron injection layer EIL in the evaporation chamber 137.

Subsequently, the first transparent layer TL1 is formed on the upper electrode UE in the evaporation chamber 138.

Subsequently, the second transparent layer TL2 is formed on the first transparent layer TL1 in the evaporation chamber 139.

The processing substrate SUB and carrier CR which passed through the fourth rail R4 are conveyed to the attaching/detaching portion 107. In the attaching/detaching portion 107, the processing substrate SUB is released from the carrier CR, is conveyed to the transfer chamber 108, and is conveyed to a CVD device (not shown).

By this process, the display element 20 comprising the organic layer OR comprising a tandem configuration is formed.

According to the manufacturing device 100 comprising the configuration described above, in the first mode for forming an organic layer comprising a single configuration, the second conveyance portion T2, the second rotation chamber 120, the storage portion 130, the evaporation chambers 127 to 129 of the second evaporation portion DP2 and the evaporation chambers 131 to 133 of the third evaporation portion DP3 can be opened to the atmosphere by closing the gate valve V3. Thus, the maintenance of each portion opened to the atmosphere can be performed.

Compared to a case where maintenance is performed by stopping the operation of an in-line evaporation device, the maintenance time is shortened, and further, the number of people necessary for maintenance can be reduced. In this manner, the efficiency of maintenance can be improved.

Moreover, if maintenance is needed for a portion such as the second evaporation portion DP2 or the third evaporation portion DP3, there is no need to stop the operation of the whole in-line evaporation device, thereby preventing the reduction in productivity.

When the first mode is performed, the conveyance path to be maintained as a vacuum is shortened.

Further, the manufacturing device 100 can form either a display element comprising a single configuration or a display element comprising a tandem configuration.

As explained above, the embodiments can provide a manufacturing device of a display device such that the efficiency of maintenance can be improved.

All of the manufacturing devices that can be implemented by a person of ordinary skill in the art through arbitrary design changes to the manufacturing device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing device of a display device, comprising:
a preprocessing portion configured to perform preprocessing for a processing substrate comprising:
a lower electrode located above a substrate;
a rib comprising an aperture which overlaps the lower electrode; and
a partition including a lower portion located on the rib and an upper portion located on the lower portion and protruding from a side surface of the lower portion;
a conveyance mechanism configured to convey the processing substrate which passed through the preprocessing portion; and
first, second, third and fourth evaporation portions arranged in order in a conveyance direction of the processing substrate by the conveyance mechanism, wherein
each of the first, second, third and fourth evaporation portions comprises a plurality of evaporation chambers, and
the conveyance mechanism comprises:
a first rail provided along the first evaporation portion;
a second rail provided along the second evaporation portion;
a third rail provided along the third evaporation portion;
a fourth rail provided along the fourth evaporation portion;
a first rotation chamber provided between the first rail and the second rail and between the third rail and the fourth rail, and configured to rotate the processing substrate which passed through the first rail and convey the processing substrate to the fourth rail;
a second rotation chamber configured to rotate the processing substrate which passed through the second rail and convey the processing substrate to the third rail; and
a gate valve provided between the first rotation chamber and the third and fourth rails.

2. The manufacturing device of claim 1, wherein
the first evaporation portion comprises an evaporation chamber for forming a first light emitting layer, and
the second evaporation portion comprises an evaporation chamber for forming an n-type charge generation layer and an evaporation chamber for forming a p-type charge generation layer.

3. The manufacturing device of claim 2, wherein
the third evaporation portion comprises an evaporation chamber for forming a second light emitting layer which emits light exhibiting a same color as the first light emitting layer.

4. The manufacturing device of claim 3, wherein
the fourth evaporation portion comprises:
an evaporation chamber for forming an upper electrode;
an evaporation chamber for forming a first transparent layer on the upper electrode; and
an evaporation chamber for forming a second transparent layer having a lower refractive index than a refractive index of the first transparent layer on the first transparent layer.

5. The manufacturing device of claim 1, wherein
the preprocessing portion comprises:
a load lock chamber in which the processing substrate is carried;
a baking portion which performs a drying process of the processing substrate;
a plasma processing portion which reforms a surface of the lower electrode; and
an attaching/detaching portion which secures the processing substrate to a carrier or detaches the processing substrate from the carrier, and
the conveyance mechanism is configured to convey the carrier to which the processing substrate is secured.

6. The manufacturing device of claim 1, wherein
in a first mode for forming an organic layer comprising a single configuration on the lower electrode,
the gate valve is closed, and
the first rotation chamber conveys the processing substrate which passed through the first rail to the fourth rail, and
in a second mode for forming an organic layer comprising a tandem configuration on the lower electrode,
the gate valve is opened,
the first rotation chamber conveys the processing substrate which passed through the first rail to the second rail, and conveys the processing substrate which passed through the third rail to the fourth rail, and
the second rotation chamber conveys the processing substrate which passed through the second rail to the third rail.

7. The manufacturing device of claim 6, wherein
in the first mode, the second evaporation portion and the third evaporation portion are opened to atmosphere.

8. The manufacturing device of claim 6, wherein
the first evaporation portion comprises a first evaporation chamber for forming a first hole blocking layer,
the fourth evaporation portion comprises a second evaporation chamber for forming a second hole blocking layer, and
in the first mode, one of the first evaporation chamber and the second evaporation chamber is maintained in a non-operation state.

9. The manufacturing device of claim 5, wherein
the attaching/detaching portion comprises a mechanism for rotating the processing substrate conveyed horizontally by 90 degrees to raise the processing substrate perpendicularly, and rotating the processing substrate conveyed perpendicularly by 90 degrees to lay down the processing substrate horizontally.

10. The manufacturing device of claim 9, wherein
the conveyance mechanism is configured to convey the processing substrate having a perpendicular posture.

11. The manufacturing device of claim 1, wherein
the first rail and the second rail extend on a same straight line,
the third rail and the fourth rail extend on a same straight line,
the first rail and the fourth rail are parallel to each other, and
the second rail and the third rail are parallel to each other.

12. The manufacturing device of claim 11, wherein
each of the first rotation chamber and the second rotation chamber comprises a rotation mechanism configured to rotate around a rotation axis, and
the rotation mechanism is configured to rotate 180° while holding the processing substrate conveyed in a perpendicular posture.

13. A manufacturing device of a display device, comprising:
a preprocessing portion configured to perform preprocessing for a processing substrate;
a conveyance mechanism configured to convey the processing substrate which passed through the processing portion; and
first, second, third and fourth evaporation portions arranged in order in a conveyance direction of the processing substrate by the conveyance mechanism, wherein
the first evaporation portion comprises an evaporation chamber for forming a first light emitting layer,
the second evaporation portion comprises an evaporation chamber for forming an n-type charge generation layer and an evaporation chamber for forming a p-type charge generation layer,
the third evaporation portion comprises an evaporation chamber for forming a second light emitting layer,
the fourth evaporation portion comprises an evaporation chamber for forming an upper electrode, and
the conveyance mechanism comprises:
a first rail provided along the first evaporation portion;
a second rail provided along the second evaporation portion;
a third rail provided along the third evaporation portion;
a fourth rail provided along the fourth evaporation portion;
a first rotation chamber provided between the first rail and the second rail and between the third rail and the fourth rail and configured to rotate the processing substrate which passed through the first rail and convey the processing substrate to the fourth rail;
a second rotation chamber configured to rotate the processing substrate which passed through the second rail and convey the processing substrate to the third rail; and
a gate valve provided between the first rotation chamber and the third and fourth rails.

14. The manufacturing device of claim 13, wherein
in a first mode for forming an organic layer comprising a single configuration,
the gate valve is closed, and
the first rotation chamber conveys the processing substrate which passed through the first rail to the fourth rail, and
in a second mode for forming an organic layer comprising a tandem configuration,
the gate valve is opened,
the first rotation chamber conveys the processing substrate which passed through the first rail to the second rail, and conveys the processing substrate which passed through the third rail to the fourth rail, and
the second rotation chamber conveys the processing substrate which passed through the second rail to the third rail.

15. The manufacturing device of claim 14, wherein
in the first mode, the second evaporation portion and the third evaporation portion are opened to atmosphere.

16. The manufacturing device of claim 14, wherein
the first evaporation portion comprises a first evaporation chamber for forming a first hole blocking layer,
the fourth evaporation portion comprises a second evaporation chamber for forming a second hole blocking layer, and
in the first mode, one of the first evaporation chamber and the second evaporation chamber is maintained in a non-operation state.

17. The manufacturing device of claim 13, wherein
the preprocessing portion comprises an attaching/detaching portion which secures the processing substrate to a carrier or detaches the processing substrate from the carrier, and
the attaching/detaching portion comprises a mechanism for rotating the processing substrate conveyed horizontally by 90 degrees to raise the processing substrate perpendicularly and rotating the processing substrate conveyed perpendicularly by 90 degrees to lay down the processing substrate horizontally.

18. The manufacturing device of claim 17, wherein
the conveyance mechanism is configured to convey the processing substrate having a perpendicular posture.

19. The manufacturing device of claim 13, wherein
the first rail and the second rail extend on a same straight line,
the third rail and the fourth rail extend on a same straight line,
the first rail and the fourth rail are parallel to each other, and
the second rail and the third rail are parallel to each other.

20. The manufacturing device of claim 19, wherein
each of the first rotation chamber and the second rotation chamber comprises a rotation mechanism configured to rotate around a rotation axis, and
the rotation mechanism is configured to rotate 180° while holding the processing substrate which was conveyed in a perpendicular posture.
